(19) United States
(12) Patent Application Publication
(10) Pub. No.: US 2026/0068209 A1
(43) Pub. Date: Mar. 5, 2026

(54) ENHANCEMENT-MODE GAN HEMT EPITAXY WAFER WITH HIGH QUALITY

(71) Applicant: WAVELORD CO., LTD, Gyeonggi-do (KR)

(72) Inventors: June O SONG, Gyeonggi-do (KR); Younghun HAN, Gyeonggi-do (KR); Hyun Chul LIM, Gyeonggi-do (KR); Jungwon KIM, Gyeonggi-do (KR); Seyong AHN, Gyeonggi-do (KR)

(21) Appl. No.: 19/310,221

(22) Filed: Aug. 26, 2025

(30) Foreign Application Priority Data
Aug. 27, 2024 (KR) 10-2024-0114933
Feb. 3, 2025 (KR) 10-2025-0013119

(51) Int. Cl. H10D 30/47; H10D 62/10; H10D 62/85

(52) U.S. Cl. CPC H10D 30/475; H10D 62/106; H10D 62/8503

(57) ABSTRACT

Embodiments according to the present invention provide a high-quality E-mode GaN HEMT power semiconductor epitaxy wafer comprises a GaN channel region in which a 2DEG (2-dimensional electron gas) is formed; an AlGaN barrier region formed on the GaN channel region; and a p-type semiconductor region formed on the AlGaN barrier region, wherein the p-type semiconductor region has a first doping region having a minimum doping concentration at a boundary with the AlGaN barrier region and an increasing magnesium (Mg) doping concentration in a thickness direction, and a second doping region having the minimum doping concentration on a back surface of the AlGaN barrier region, in which the magnesium (Mg) doping concentration decreases in a thickness direction after passing a maximum doping concentration.

### CROSS-REFERENCE TO RELATED APPLICATIONS

This application claims the benefit and priority to Korean Patent Application Nos. 10-2024-0114933, filed Aug. 27, 2024 and 10-2025-0013119, filed on Feb. 3, 2025. The entire disclosures of the applications identified in this paragraph are incorporated herein by references.

### FIELD

The present invention relates to an E-mode GaN HEMT power semiconductor epitaxy wafer, and is characterized by preventing deterioration of 2DEG channel characteristics during the growth process of a p-type semiconductor region for forming a 2DEG channel in a normally off state (E-mode) and improving gate breakdown voltage characteristics.

### BACKGROUND

GaN power semiconductor devices are increasingly in demand due to their high-frequency switching, high-current carrying, and high-voltage capabilities.

These devices have been developed primarily for high-power/high-frequency applications.

Devices manufactured for these applications are based on common device structures exhibiting high electron mobility and are variously referred to as heterojunction field effect transistors (FETs), high electron mobility transistors (HEMTs), or modulation doped field effect transistors (MODFETs).

These types of devices can typically withstand high voltages, such as 30 V to 2000 V, while operating at high frequencies, such as 100 kHz to 100 GHz.

GaN HEMT power semiconductor epitaxy structures typically consist of a channel region and a barrier region sequentially stacked on a growth substrate.

To minimize crystal defects such as dislocations and surface pits, prevent leakage current, and ensure effective heat dissipation, sublayers such as nucleation regions, stress-relieving regions, and buffer regions are formed between the growth substrate and the channel region.

The channel region and barrier region serve as the core active regions of GaN HEMT power semiconductor devices.

The active region, in the Al(1−y)Ga(y)N (barrier)/GaN (channel) heterojunction, forms a horizontal channel with a high electron density (2DEG) due to the polarization of the group III nitride semiconductor, even without intentional doping, at the GaN channel region interface, which has a small energy bandgap.

Polarization intensity is determined by the Al composition and thickness of the Al(1−y)Ga(y)N layer, and the thickness is typically controlled by the Al composition.

In some cases, an AlN film less than 5 nm thick can be introduced prior to growing the Al(1−y)Ga(y)N barrier region over the GaN channel region.

Meanwhile, there are examples of p-type group III nitride (GaN, AlGaN, InGaN, AlInN, AlGaInN) films being introduced over the Al(1−y)Ga(y)N barrier region.

Since the 2DEG region exists beneath the gate under zero gate bias, it is normally on.

P-type group III nitride thin films function as an enhancement mode, where the 2DEG region is depleted (i.e., electron depleted) beneath the gate under zero gate bias, creating a normally off state. This provides safety and ease of control.

However, the process of doping p-type group III nitride thin films with magnesium (Mg) has the problem of deteriorating the 2DEG region properties due to Mg diffusion during the process.

### SUMMARY

### Technical Problem

The present invention provides a high-quality E-mode GaN HEMT power semiconductor epitaxy wafer that improves the deterioration of 2DEG channel characteristics during the growth process of a p-type semiconductor region for a normally off (E-mode) channel region.

The present invention also provides a high-quality E-mode GaN HEMT power semiconductor epitaxy wafer that reduces magnesium back-diffusion into the barrier region during the growth process of the p-type semiconductor region, thereby preventing impurities from entering the 2DEG channel or its degradation.

The present invention also provides a high-quality E-mode GaN HEMT power semiconductor epitaxy wafer that improves gate breakdown voltage characteristics by increasing the thickness and height of the Schottky barrier at the boundary between the p-type semiconductor region and the gate electrode.

### Technical Solution

Embodiments of the present invention include an E-mode GaN HEMT power semiconductor epitaxy wafer, comprising: a GaN channel region formed with a 2DEG (2-dimensional electron gas); an AlGaN barrier region formed over the GaN channel region; and a p-type semiconductor region formed over the AlGaN barrier region, and wherein the p-type semiconductor region has a first doping region having a minimum doping concentration at the boundary with the AlGaN barrier region and an increasing magnesium (Mg) doping concentration in the thickness direction; and a second doping region having the minimum doping concentration on the back surface of the AlGaN barrier region, after passing a maximum doping concentration, a decreasing magnesium (Mg) doping concentration in the thickness direction.

The magnesium (Mg) doping concentration of the p-type semiconductor region is minimum on both sides of the p-type semiconductor region in the thickness direction, and maximum in the interior. This prevents deterioration of 2DEG channel characteristics due to Mg back-diffusion and improves gate breakdown voltage characteristics.

In embodiments according to the present invention, the change in the growth conditions is performed by relatively lowering the growth pressure and/or the growth temperature to increase the carbon concentration. The Mg doping concentration is minimal and equal on both sides of the p-type semiconductor region in the thickness direction.

In embodiments according to the present invention, the p-type semiconductor region may have a maximum doping region maintained at the maximum doping concentration in the thickness direction. In this case, it is preferable to adjust the value of the maximum doping concentration and the thickness of the maximum doping region so that the average Mg doping concentration in the p-type semiconductor region is between E+19 and 9E+19/cm³.

In embodiments according to the present invention, the p-type semiconductor region may be configured such that the magnesium (Mg) doping concentration continuously increases or decreases in the first and second doping regions. Here, the continuous increase in the magnesium (Mg) doping concentration is not limited to a linear pattern and may also be a curve.

In embodiments of the present invention, the p-type semiconductor region may be configured such that the magnesium (Mg) doping concentration discontinuously increases or decreases in the first and second doping regions. In this case, the p-type semiconductor region may be configured such that the magnesium (Mg) doping concentration increases or decreases stepwise in the first and second doping regions.

Furthermore, the p-type semiconductor region may have an undoped region in which magnesium (Mg) doping does not occur in the first and second doping regions. The undoped region functions to improve the crystal quality of the p-type semiconductor region. The undoped region does not necessarily have to be formed symmetrically on both sides around the maximum doping region.

In embodiments of the present invention, the p-type semiconductor region may be formed of p-type GaN, or may contain 3% or less of Al or In. A small amount of Al or In has the effect of improving the crystal quality of the p-type GaN.

In embodiments of the present invention, the minimum doping concentration is preferably 0 to 1.0E+18/cm³, and the maximum doping concentration is preferably 8.0E+19 to 1.0E+20/cm³. If the maximum doping concentration exceeds 1.0E+20/cm³, excessive doping may occur, which may cause a deterioration in the crystal quality of the p-type semiconductor region.

Embodiments of the present invention may include a growth substrate as the lower layer of the GaN channel region; an AlN nucleation region formed on the growth substrate; an AlGaN stress relief region formed on the AlN nucleation region; and a buffer region formed on the AlGaN stress relief region.

### Advantageous Effects

According to the present invention, by forming a p-type semiconductor region with a minimum doping concentration at the AlGaN barrier region and its boundary, and with an increasing magnesium (Mg) doping concentration in the thickness direction, Mg back-diffusion into the barrier region can be reduced. Therefore, impurity inflow into the channel region where the 2DEG is formed or degradation of the channel region can be prevented.

According to the present invention, the magnesium (Mg) doping concentration in the p-type semiconductor region is configured to have a minimum doping concentration that is the same on both sides in the thickness direction, and a maximum doping concentration within the region. This increases the thickness and height of the Schottky barrier at the boundary between the p-type semiconductor region and the gate electrode, thereby improving gate breakdown voltage characteristics.

### BRIEF DESCRIPTION OF DRAWINGS

FIG. 1 is a diagram illustrating an E-mode GaN HEMT power semiconductor epitaxy wafer according to one embodiment of the present invention.

FIG. 2 is a detailed diagram illustrating the p-type semiconductor region of FIG. 1.

FIGS. 3, 4 and 5 are diagrams illustrating examples of doping profiles of the p-type semiconductor region.

FIG. 6 is a diagram illustrating an E-mode GaN HEMT power semiconductor device using the E-mode GaN HEMT power semiconductor epitaxy wafer of FIG. 1.

### DETAILED DESCRIPTION

Hereinafter, a high-quality E-mode GaN HEMT power semiconductor epitaxy wafer according to embodiments of the present invention will be described in detail with reference to the drawings.

In this process, the thicknesses of the layers or regions depicted in the drawings are exaggerated for clarity of the specification. Furthermore, the terms used below have been selected for convenience of explanation and should be interpreted in a way that is consistent with the technical concept of the present invention, without being limited by their dictionary meanings.

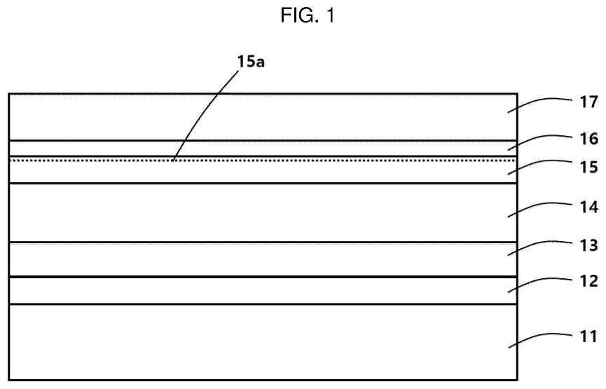

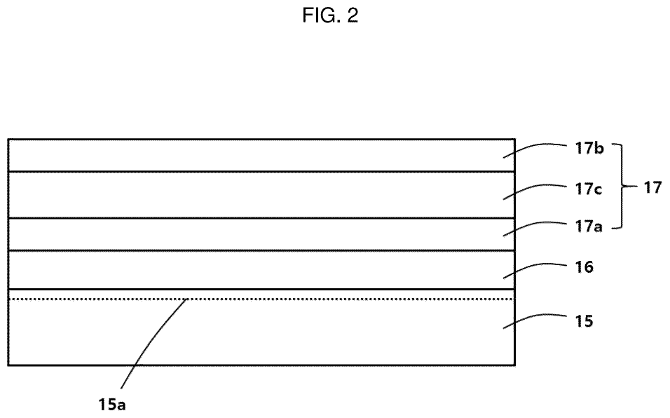

Referring to FIGS. 1 to 3, a high-quality E-mode GaN HEMT power semiconductor epitaxy wafer according to the present embodiment includes a GaN channel region (15), an AlGaN barrier region (16), and a p-type semiconductor region (17).

The heterojunction of the GaN channel region (15) and the AlGaN barrier region (16) forms a 2DEG (2-dimensional electron gas) region (15a) at the interface of the GaN channel region (15) with a small energy band gap due to the polarization phenomenon of the group III nitride semiconductor.

The polarization intensity is determined by the Al composition and thickness of the AlGaN barrier region (16), and the thickness is typically controlled based on the Al composition. In some cases, an AlN thin film less than 5 nm thick can be introduced prior to growing the AlGaN barrier region (16) over the GaN channel region (15).

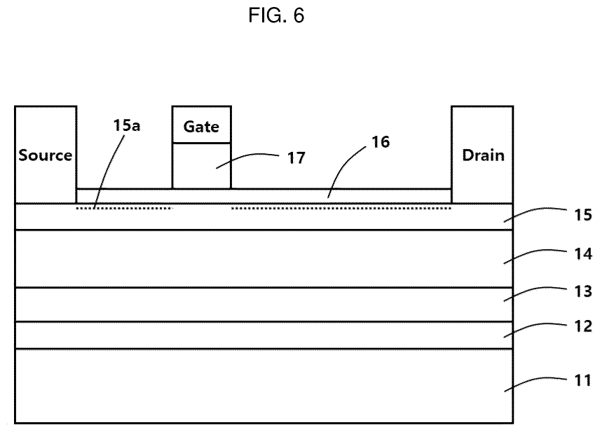

The p-type semiconductor region (17) is provided to function as a normally off state by removing electrons from the 2DEG region (15a) beneath the gate electrode (Gate) when a positive field is applied to the gate electrode (see FIG. 6) through electron depletion.

The p-type semiconductor region (17) can be formed of a p-type Group III nitride, such as GaN, AlGaN, InGaN, AlInN, or AlGaInN.

The p-type semiconductor region (17) is doped with magnesium (Mg). In this embodiment, the p-type semiconductor region (17) has multiple regions with different doping concentrations in the thickness direction.

Specifically, the p-type semiconductor region (17) has a first doped region (17a) with a minimum doping concentration at the boundary with the AlGaN barrier region (16) and an increasing magnesium (Mg) doping concentration in the thickness direction.

Furthermore, after passing the maximum doping concentration, the magnesium (Mg) doping concentration decreases in the thickness direction, resulting in a second doped region (17b) with a minimum doping concentration on the back surface of the AlGaN barrier region (16).

In other words, the magnesium (Mg) doping concentration of the p-type semiconductor region (17) is minimum on both sides in the thickness direction and maximum in the interior. Furthermore, it is preferable that the magnesium (Mg) doping concentration of the p-type semiconductor region (17) be the same on both sides in the thickness direction.

Here, the minimum doping concentration is preferably 0 to 1.0E+18/cm³, and the maximum doping concentration is preferably 8.0E+19 to 1.0E+20/cm³.

If the maximum doping concentration exceeds 1.0E+20/cm3, excessive doping may occur, which may degrade the crystal quality of the p-type semiconductor region.

This prevents deterioration of the characteristics of the 2DEG region (15a) due to Mg back-diffusion and improves the gate breakdown voltage characteristics.

In this embodiment, the p-type semiconductor region (17) is preferably provided with a maximum doping region (17c) maintained at the maximum doping concentration in the thickness direction.

At this time, it is preferable to adjust the maximum doping concentration and the thickness of the maximum doping region so that the average Mg doping concentration in the p-type semiconductor region is 1E+19 to 9E+19/cm³.

Furthermore, the p-type semiconductor region (17) is configured such that the magnesium (Mg) doping concentration continuously increases or decreases in the first and second doping regions (17a, 17b).

The continuous increase and decrease in the magnesium (Mg) doping concentration is not limited to a linear pattern and may also be a curve.

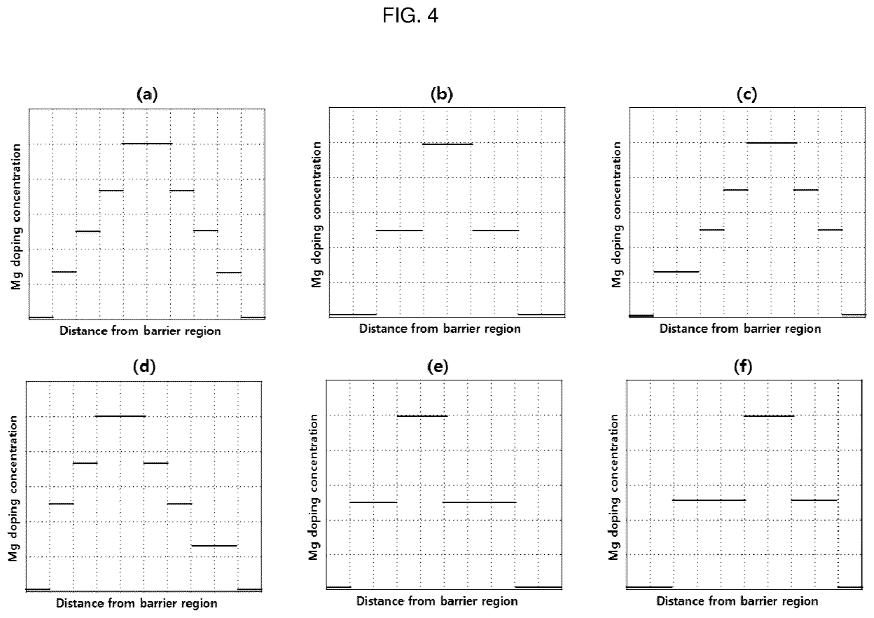

Referring to FIG. 4, this embodiment differs from the previously described embodiment in that the magnesium (Mg) doping concentration is provided to discontinuously increase or decrease in the first and second doping regions (17a, 17b) of the p-type semiconductor region (17), and the rest is the same.

The discontinuous increase and decrease in the magnesium (Mg) doping concentration can be configured such that the magnesium (Mg) doping concentration in the first and second doping regions (17a, 17b) increases or decreases in a stepwise manner.

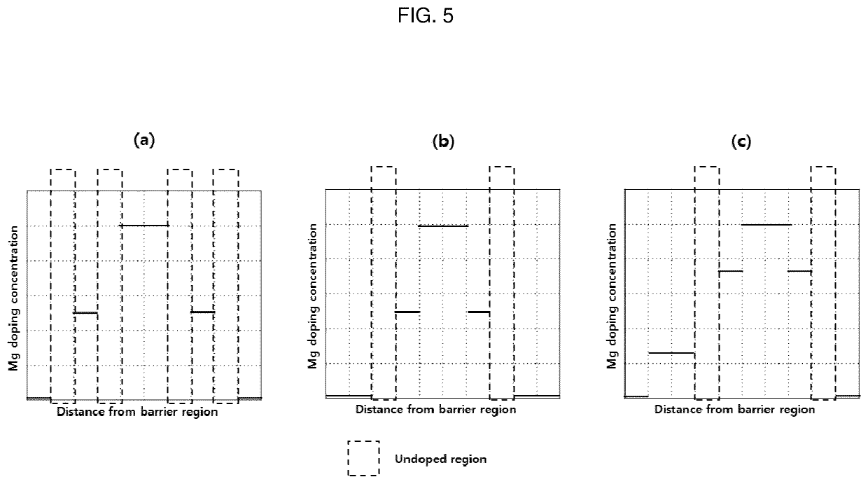

Referring to FIG. 5, this embodiment is different from the previously described embodiments in that it is provided with an undoped region in which magnesium (Mg) doping is not performed in the first and second doping regions (17a, 17b) of the p-type semiconductor region (17), and the rest is the same.

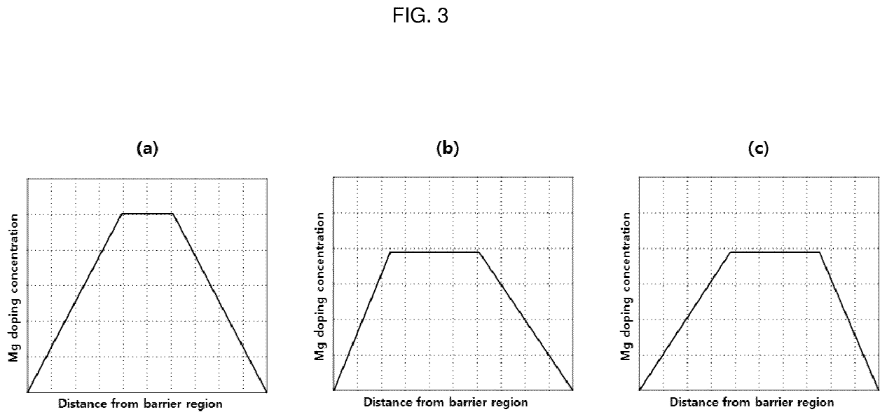

Although FIG. 5 shows that the undoped region is applied when the magnesium (Mg) doping concentration increases or decreases stepwise, it does not exclude that the undoped region is applied when the magnesium (Mg) doping concentration increases and decreases continuously as in FIG. 3.

The undoped region functions to improve the crystal quality of the p-type semiconductor region (17).

The undoped region does not necessarily have to be formed symmetrically on both sides around the maximum doping region.

Meanwhile, in the previously described embodiments, the p-type semiconductor region (17) preferably contains 3% or less of Al or In. Small amounts of Al and In have the effect of improving the crystal quality of the p-type semiconductor region (17).

In addition, the embodiments described above may include sublayers, such as a nucleation region (12), a stress-relieving region (13), and a buffer region (14), between the growth substrate (11) and the GaN channel region (15).

This configuration minimizes crystal defects, prevents leakage current, and provides effective heat dissipation.

The growth substrate (11) may be, for example, a silicon substrate, a silicon carbide (SiC) substrate, or an aluminum oxide substrate. The aluminum oxide substrate may be, for example, an Al₂O₃ substrate.

It is preferable for the silicon (Si) growth substrate to be grown on the (111) plane, which has a high atomic packing ratio, such as a group III nitride crystal structure (HCP), rather than on the (100) or (110) plane.

The silicon carbide (SiC) growth substrate is preferably a 4H-SiC growth substrate, which has the same crystal structure as the Group III nitride (HCP) crystal structure and the smallest lattice constant difference. Growth on the Si-polar face is preferred.

The nucleation region (12) promotes the formation of high-quality buffer and active regions (channel and barrier regions), and AlN may be preferentially employed.

The stress relaxation region (13) may be an AlGaN thin film layer containing a large amount of gallium (Ga) to suppress wafer warpage or cracking caused by tensile stress within the GaN material layer due to thermo-mechanical stress when a GaN thin film or thick film is grown on the growth substrate (11) and cooled to room temperature.

In contrast, the stress relief region (13) may be composed of multiple layers with different gallium (Ga) compositions, may be formed by gradually increasing the gallium (Ga) composition, or may be formed as an Al(Ga)N/AlGaN superlattice structure.

The buffer region (14) is a current blocking region that reduces vertical leakage current by imparting high-resistive properties. This function can be achieved by doping with carbon (C), iron (Fe), nickel (Ni), cobalt (Co), rare-earth metals, etc.

According to the present invention described above, by reducing the Mg doping concentration in the region adjacent to the AlGaN barrier region, the Mg back-diffusion phenomenon is reduced, preventing the inflow of Mg impurities into the 2DEG region and thus preventing deterioration of electrical characteristics.

Additionally, a decrease in the Mg doping concentration near the contact between the p-type semiconductor region and the gate electrode can increase the thickness and height of the Schottky barrier, thereby increasing the gate breakdown voltage characteristics.

What is claimed is:

1. A high-quality E-mode GaN HEMT power semiconductor epitaxy wafer comprising:
a GaN channel region in which a 2DEG (2-dimensional electron gas) is formed;
an AlGaN barrier region formed over the GaN channel region; and
a p-type semiconductor region formed over the AlGaN barrier region;
wherein the p-type semiconductor region has a first doping region having a minimum doping concentration at a boundary with the AlGaN barrier region and an increasing magnesium (Mg) doping concentration in a thickness direction; and a second doping region having the minimum doping concentration on the back surface of the AlGaN barrier region, in which the magnesium (Mg) doping concentration decreases after passing a maximum doping concentration.

2. The high-quality E-mode GaN HEMT power semiconductor epitaxy wafer of claim 1, wherein the p-type semiconductor region has a maximum doping region maintained at the maximum doping concentration in the thickness direction therein.

3. The high-quality E-mode GaN HEMT power semiconductor epitaxy wafer of claim 2, wherein the p-type semiconductor region has a magnesium (Mg) doping concentration that continuously increases or decreases in the first and second doping regions.

4. The high-quality E-mode GaN HEMT power semiconductor epitaxy wafer of claim 2, wherein the p-type semiconductor region has a magnesium (Mg) doping concentration that discontinuously increases or decreases in the first and second doping regions.

5. The high-quality E-mode GaN HEMT power semiconductor epitaxy wafer of claim 4, wherein the p-type semiconductor region has a magnesium (Mg) doping concentration that increases or decreases stepwise in the first and second doping regions.

6. The high-quality E-mode GaN HEMT power semiconductor epitaxy wafer of claim 5, wherein the p-type semiconductor region has an undoped region in which magnesium (Mg) doping is not performed in the first and second doping regions.

7. The high-quality E-mode GaN HEMT power semiconductor epitaxy wafer of claim 1, wherein the p-type semiconductor region is made of p-type GaN.

8. The high-quality E-mode GaN HEMT power semiconductor epitaxy wafer of claim 7, wherein the p-type semiconductor region contains Al or In in a composition of 3% or less.

9. The high-quality E-mode GaN HEMT power semiconductor epitaxy wafer of claim 1, wherein the minimum doping concentration is 0 to 1.0E+18/cm³, and the maximum doping concentration is 8.0E+19 to 1.0E+20/cm³.

10. A high-quality E-mode GaN HEMT power semiconductor epitaxy wafer comprising:
a growth substrate;
an AlN nucleation region formed on the growth substrate;
an AlGaN stress relief region formed on the AlN nucleation region;
a buffer region formed on the AlGaN stress relief region;
a GaN channel region formed on the buffer region with a 2DEG (2-dimensional electron gas) formed thereon;
an AlGaN barrier region formed on the GaN channel region; and
a p-type semiconductor region formed on the AlGaN barrier region;
wherein the p-type semiconductor region comprises a first doping region in which the magnesium (Mg) doping concentration increases in the thickness direction from the boundary of the AlGaN barrier region; and a second doping region in which the magnesium (Mg) doping concentration decreases in the thickness direction after passing a maximum doping concentration, wherein the magnesium (Mg) doping concentration is the same on both sides in the thickness direction and has a minimum doping concentration.
